(19) United States
(12) Patent Application Publication
(10) Pub. No.: US 2015/0262832 A1
(43) Pub. Date: Sep. 17, 2015

(54) MANUFACTURING METHOD OF SEMICONDUCTOR DEVICE

(71) Applicant: Kabushiki Kaisha Toshiba, Minato-ku (JP)

(72) Inventors: Keisuke KIKUTANI, Yokkaichi (JP); Yuta WATANABE, Yokkaichi (JP); Kazunori NISHIKAWA, Suzuka (JP)

(73) Assignee: Kabushiki Kaisha Toshiba, Minato-ku (JP)

(21) Appl. No.: 14/479,590

(22) Filed: Sep. 8, 2014

Related U.S. Application Data
(60) Provisional application No. 61/952,457, filed on Mar. 13, 2014.

(51) Int. Cl. H01L 21/308; H01L 21/3213; H01L 21/033

(52) U.S. Cl. CPC H01L 21/3086; H01L 21/0337; H01L 21/32139

(57) ABSTRACT

In accordance with an embodiment, a manufacturing method of a semiconductor device includes manufacturing a mask pattern and forming an interconnection using the mask pattern. The manufacturing the mask pattern includes forming a first pattern of a first material, depositing a second material over the first pattern, forming a first sidewall film on sidewalls of the first pattern by a first etchback, depositing a third material over the first sidewall film, forming a second sidewall film on sidewalls of the first sidewall film by a second etchback, adjusting the first pattern and second sidewall film so as to have the same height, and selectively removing the first sidewall film. The first pattern has a line width of a first width equal to the thicknesses of the first and second sidewall films. The mask pattern includes a line-and-space having a line width and a space equal to the first width, respectively.

### CROSS REFERENCE TO RELATED APPLICATIONS

This application is based upon and claims the benefit of U.S. provisional Application No. 61/952,457, filed on Mar. 13, 2014, the entire contents of which are incorporated herein by reference.

### FIELD

Embodiments described herein relate generally to a manufacturing method of a semiconductor device.

### BACKGROUND

There has been known one method of forming a pattern having a line width which is ⅓ of a pitch width of an exposure dimension. According to this method, a first mask pattern (core material) having a line width which is ⅓ of the exposure dimension is formed. A first sidewall film (sacrifice film) is then formed in such a manner that the line width will be ⅓ of the exposure dimension, and the first sidewall film (sacrifice film) is then etched back. A second sidewall film is formed on the sidewall of the first sidewall film (sacrifice film), and then etched back. The first sidewall film (sacrifice film) is then removed to create a desired line-and-space mask composed of the first mask and the second sidewall film.

According to the method described above, a process of etching back the first sidewall film (sacrifice film) is performed before the formation of the second sidewall film, so that the first mask and the second sidewall film differ in height as a result of two etchback processes. If the underlayer transfer film is dry-etched by the use of masks different in height, the transfer film is fabricated with different conversion differences. Therefore, there has been a problem of variation in the finished wiring width of the foundation fabrication target film.

### BRIEF DESCRIPTION OF THE DRAWINGS

In the accompanying drawings:

FIG. 1 and FIG. 2 are an exemplary plan view and an exemplary sectional view showing an example of a mask pattern according to Embodiment 1;

FIG. 3 to FIG. 10 are exemplary process sectional views illustrating a first manufacturing method of the mask pattern shown in FIG. 1 and FIG. 2;

FIG. 11 to FIG. 15 are exemplary process sectional views illustrating a second manufacturing method of the mask pattern shown in FIG. 1 and FIG. 2;

FIG. 16 is a plan view showing an example of a mask pattern according to Embodiment 2;

FIG. 17 is an exemplary sectional view taken along the line A-A in FIG. 16;

FIG. 18A to FIG. 25 are exemplary process charts illustrating a manufacturing method of the mask pattern according to Embodiment 2;

FIG. 26 is a plan view showing an example of the mask pattern shown in FIG. 16;

FIG. 27 is an exemplary process chart illustrating a manufacturing method of the mask pattern shown in FIG. 26;

FIG. 28 is a plan view schematically showing the general configuration of a mask pattern according to Embodiment 3;

FIG. 29 is an exemplary sectional view taken along the line C-C in FIG. 28;

FIG. 30 is an exemplary partial enlarged view of the mask pattern shown in FIG. 28;

FIG. 31 is an exemplary sectional view taken along the line D-D in FIG. 28;

FIG. 32A to FIG. 50 are exemplary process charts illustrating a manufacturing method of the mask pattern according to Embodiment 3; and

FIG. 51 is an exemplary flowchart illustrating a manufacturing method of a semiconductor device according to an embodiment.

### DETAILED DESCRIPTION

In accordance with an embodiment, a manufacturing method of a semiconductor device includes manufacturing a mask pattern and forming an interconnection using the mask pattern. The manufacturing the mask pattern includes forming, on a fabrication target film, a first pattern of a first material, depositing a second material over the first pattern, and forming a first sidewall film on sidewalls of the first pattern by a first etchback, depositing a third material over the first sidewall film, forming a second sidewall film on sidewalls of the first sidewall film by a second etchback, and adjusting the first pattern and the second sidewall film so as to have the same height, and selectively removing the first sidewall film, thereby forming a mask pattern on the fabrication target film. The first pattern has a line width of a first width. The thickness of the first sidewall film is equal to the first width. The thickness of the second sidewall film is equal to the first width. The mask pattern includes a line-and-space. The line-and-space has a line width and a space width equal to the first width.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus. For these differences, a skilled person could make proper modifications in design by reference to the following explanations and known arts.

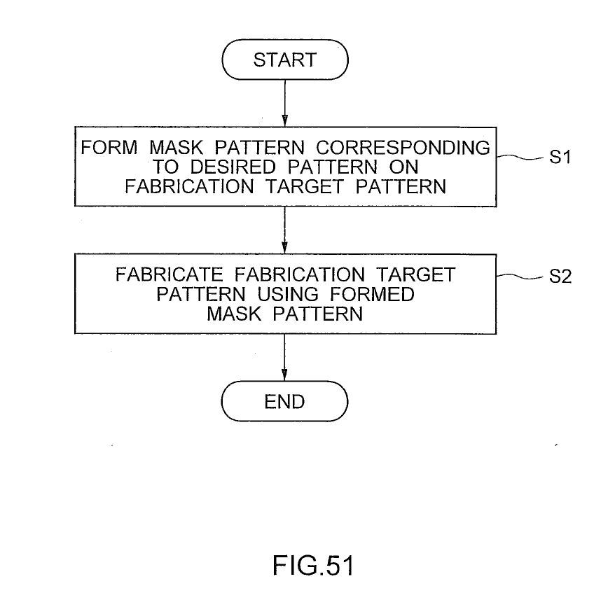

With reference to a flowchart shown in FIG. 51, a manufacturing method of a semiconductor device according to an embodiment is explained.

At first, a mask pattern corresponding to a desired pattern is formed on a fabrication target film (step S1). Then, using the formed mask pattern as a mask the fabrication target film is fabricated (step S2). Consequently, it is possible to manufacture a semiconductor device including a satisfactory pattern, e.g. a wiring pattern without causing dimensional variation.

Hereinafter, mask patterns and manufacturing methods thereof are described which enable to manufacture such a semiconductor device as Embodiments 1 through 3.

### (1) Embodiment 1

### (a) Mask Pattern

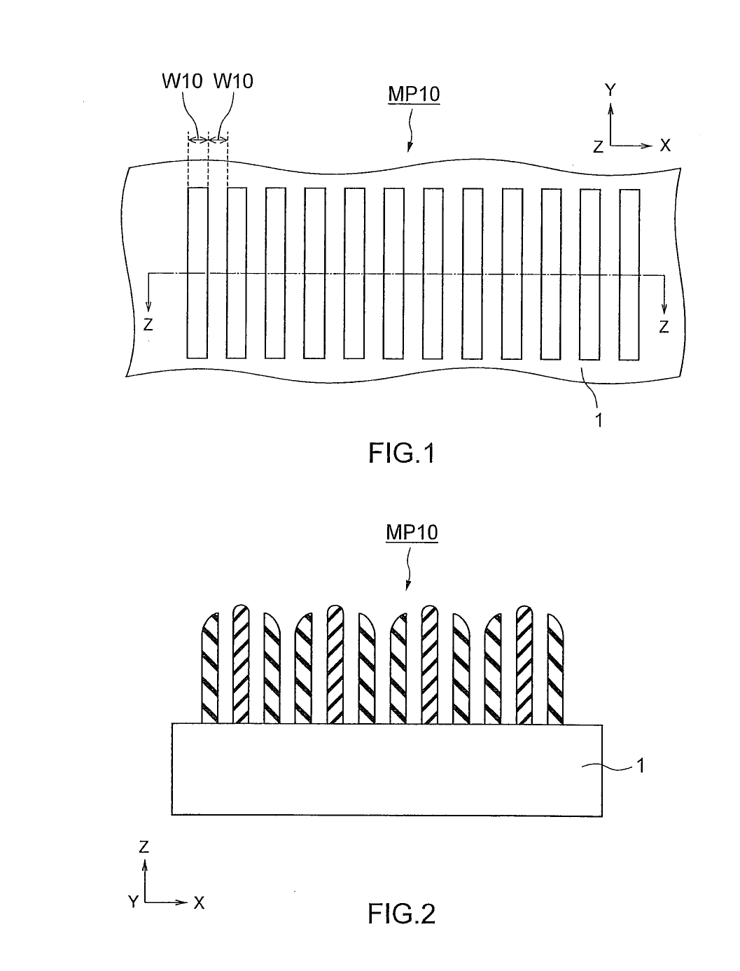

FIG. 1 is a plan view showing an example of a mask pattern according to Embodiment 1. FIG. 2 is a sectional view taken along the line Z-Z in FIG. 1.

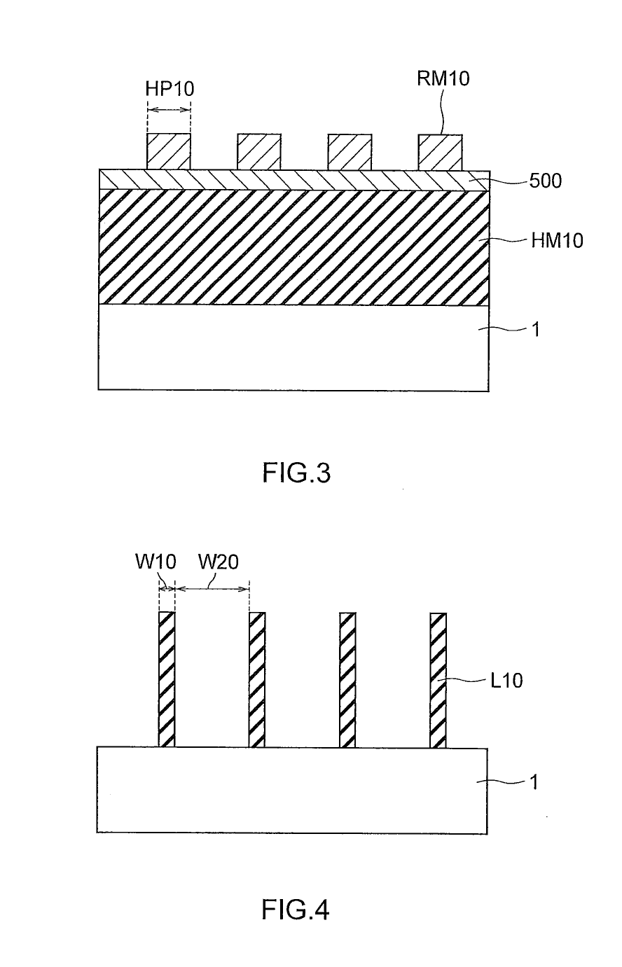

As shown in FIG. 1, a mask pattern MP10 according to the present embodiment is a line-and-space pattern formed on a fabrication target film 1, and both the line width and the space width are the same width W10. As will be described in detail later, this width W10 is ⅓ of the line width of a resist mask, that is, a half pitch (see the sign HP in FIG. 3). By way of example, the width W10 is 15 nm when the half pitch of the resist mask is 45 nm.

While the mask pattern MP10 according to the present embodiment is a line-and-space pattern having a small pitch, the mask pattern MP10 has almost no variation in the height of the claws at the tops of the lines as shown in FIG. 2. Thus, it is possible to form a satisfactory pattern without dimensional variation resulting from the fabrication of the fabrication target film 1 using the mask pattern MP10.

### (b) First Manufacturing Method

Now, a first manufacturing method of the mask pattern MP10 shown in FIG. 1 and FIG. 2 is described with reference to FIG. 3 to FIG. 10. FIG. 3 is an exemplary process sectional view taken along the line Z-Z in FIG. 1. FIG. 4 to FIG. 10 are exemplary sectional views each showing a process that follows a process shown in the drawing having a number lower by one. A target half pitch dimension in a finished state is 15 nm.

First, as shown in FIG. 3, a first hard mask HM10 is formed on the fabrication target film 1. The first hard mask HM10 can be formed, for example, by forming a silicon oxide (SiO₂) film on the fabrication target film 1 of amorphous silicon (a-Si) in a chemical vapor deposition (CVD) process. A bottom anti-reflective coating (BARC) 500 having a thickness of, for example, 30 nm is then formed on the hard mask HM10 as an antireflection film.

A line-and-space resist mask PM10 having a half pitch HP10 of 45 nm is then formed on the BARC 500 by, for example, an ArF immersion exposure technique.

The BARC 500 and the hard mask HM10 of silicon oxide (SiO₂) are then fabricated by a reactive ion etching (RIE) process using an etching gas such as carbon tetrafluoride (CF₄), haloform (CHF₃), or octafluoro-2-butene (C₄F₈). A resist RM10 and remaining films of the BARC 500 are then removed by the use of an oxygen (O₂) gas.

The hard mask HM10 of silicon oxide (SiO₂) is then slimmed by the use of a chemical such as a dilute hydrofluoric acid in a wet process in such a manner that the line width of the hard mask HM10 will be 15 nm. As a result, as shown in FIG. 4, a first pattern L10 having a line width W10 of 15 nm and a space width W20 of 75 nm is formed. In the present embodiment, silicon oxide (SiO₂) corresponds to, for example, a first material.

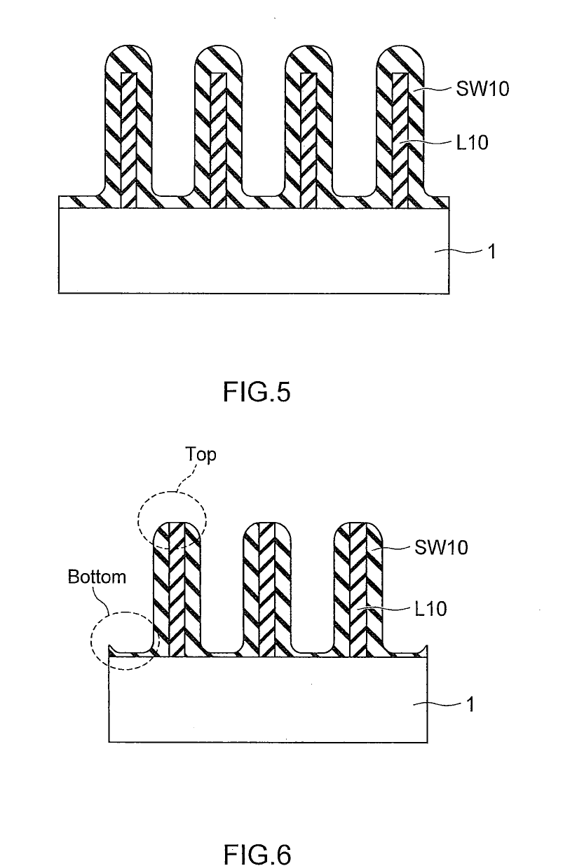

As shown in FIG. 5, a first sidewall film SW10 made of carbon is formed with a good coverage from the top of the first pattern L10 of silicon oxide (SiO₂) by a plasma enhanced (PE)-CVD apparatus using a gas such as cyclopropane (C₃H₆) or ethylene (C₂H₄). The film formation temperature in this case is, for example, 300° C. to 500° C. The thickness of the first sidewall film SW10 is previously adjusted to W10 (=15 nm). In the present embodiment, carbon corresponds to, for example, a second material.

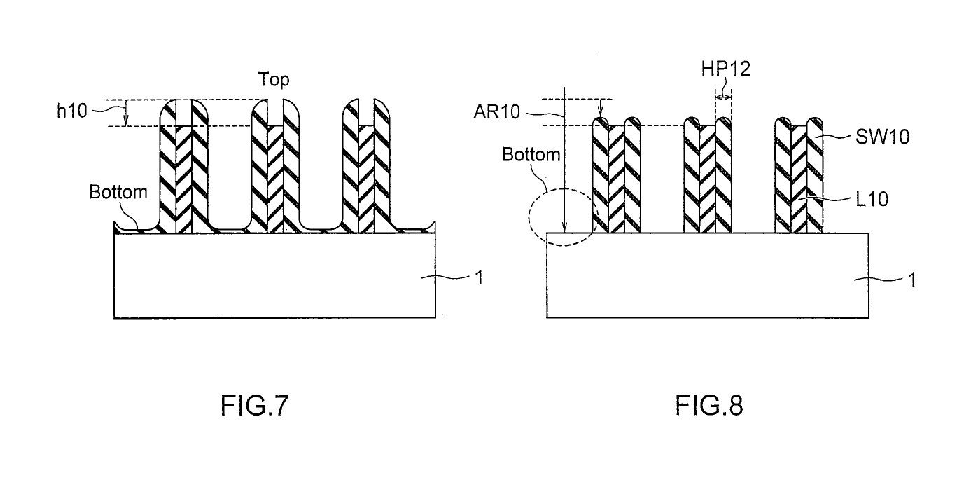

The first sidewall film SW10 is then etched back by an RIE process mainly using an oxygen (O₂) gas. In this RIE process, there is a difference of etching rates between the top of the first sidewall film SW10 and the bottom of a narrow space. Therefore, as shown in FIG. 6, the etching gas is changed by the timing where the top first falls out and the top of the first pattern immediately thereunder is exposed. More specifically, if, for example, the octafluoro-2-butene (C₄F₈) gas which allows for a selection ratio to the carbon material is used, the first pattern L10 can be selectively etched back. As a result, as shown in FIG. 7, the top surface of the first pattern L10 is lower than the top surface of the first sidewall film SW10 by a height h10. This height h10 is a height necessary to obtain the same height as the height of a later-described second sidewall film SW20 in a finished shape.

An etchback using the oxygen (O₂) gas is then performed again, and etching is performed until the bottom of the first sidewall film SW10 in the narrow space completely falls out as indicated by the arrow AR10 in FIG. 8. The thickness of the first sidewall film SW10 when formed is previously adjusted in such a manner that the thickness of the sidewall of the first sidewall film SW10 after etched will be 15 nm.

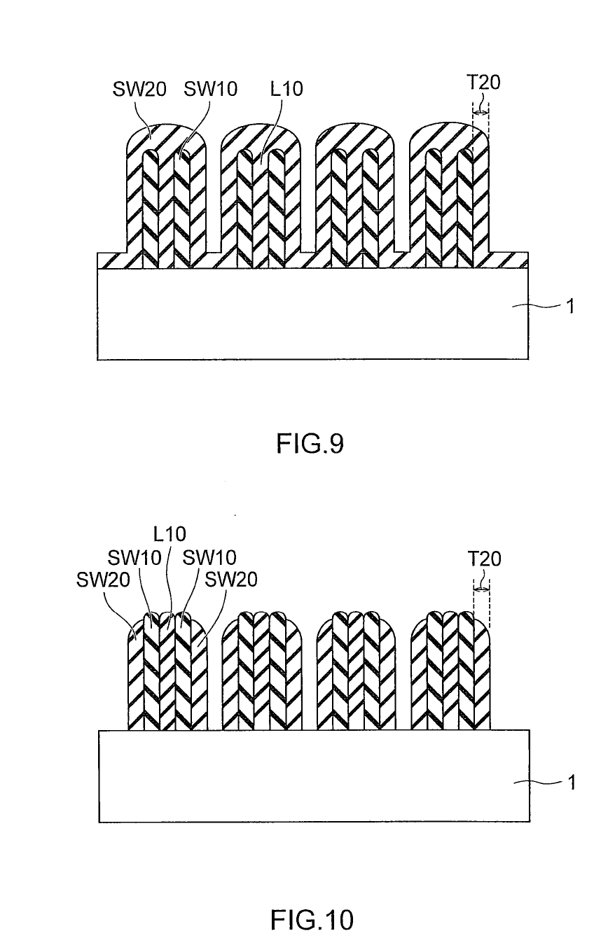

As shown in FIG. 9, the second sidewall film SW20 is then formed from the tops of the first pattern L10 and the first sidewall film SW10. This is possible if silicon oxide (SiO₂) is formed with a good coverage by, for example, an atomic layer deposition (ALD) apparatus using disilane (Si₂H₄) and the oxygen (O₂) gas. During the formation of silicon oxide (SiO₂), it is necessary to take into consideration a temperature and a plasma condition such that the first sidewall film SW10 is not damaged. For example, the film formation temperature is set at less than 500° C. During the formation of silicon oxide (SiO₂), the thickness of silicon oxide (SiO₂) is set after previously adjusted in such a manner that the thickness of the sidewall of the second sidewall film SW20 will be 15 nm. In the present embodiment, silicon oxide (SiO₂) corresponds to, for example, a third material.

As shown in FIG. 10, the second sidewall film SW20 is then etched back by the RIE process using an etching gas such as carbon tetrafluoride (CF₄), haloform (CHF₃), or octafluoro-2-butene (C₄F₈).

Furthermore, the first sidewall film SW10 is removed by the use of the oxygen (O₂) gas, the mask pattern MP10 shown in FIG. 1 and FIG. 2 is then obtained.

Thus, according to the manufacturing method of the mask pattern in the present embodiment, the first sidewall film SW10 is used as a sacrifice film to form the mask pattern by the first pattern L10 and the second sidewall film SW20, so that the line-and-space silicon oxide (SiO₂) hard mask with an HP10 of 15 nm is provided.

The manufacturing method of the mask pattern in the present embodiment includes the process of lowering the first pattern L10 by the height h10 corresponding to the difference between the height of the first pattern L10 and the height of the second sidewall film SW20 resulting from the etchback during the formation of the first sidewall film SW10. Thus, the difference between the height of the first pattern L10 and the height of the second sidewall film SW20 has been already adjusted, so that a mask pattern in which the variation of height between the first pattern L10 and the second sidewall film SW20 is small is provided. Consequently, by fabricating a foundation fabrication target film with the use of such a mask pattern, it is possible to form a satisfactory pattern without causing dimensional variation.

### (c) Second Manufacturing Method

Now, a second manufacturing method of the mask pattern according to Embodiment 1 is described with reference to FIG. 3 to FIG. 5 and FIG. 11 to FIG. 15. The present embodiment provides a method different from the above-described first manufacturing method to manufacture the mask pattern MP10 shown in FIG. 1 and FIG. 2. Therefore, a target half pitch dimension in a finished state is also 15 nm.

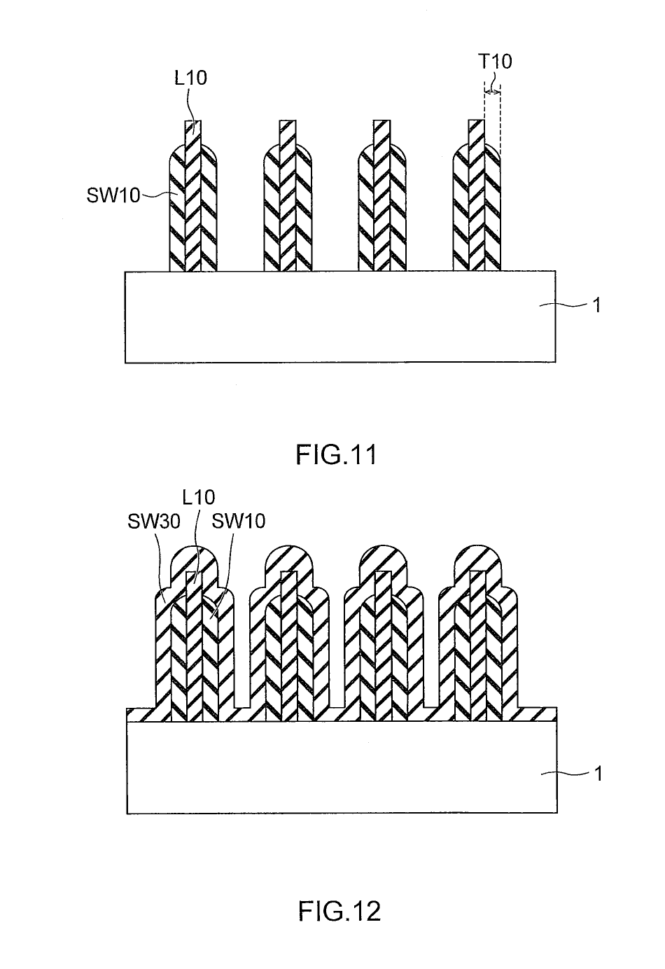

FIG. 11 is an exemplary sectional view showing a process that follows the process shown FIG. 5. FIG. 12 to FIG. 15 are exemplary sectional views each showing a process that follows a process shown in the drawing having a number lower by one.

First, the first pattern L10 having the line width W10 (HP10×⅓) and the space width W20 (HP10× 5/3) is formed on the fabrication target film 1 as in Embodiment 1 described above, and the first sidewall film SW10 made of carbon is formed over the first pattern L10.

More specifically, the first hard mask HM10 is formed, for example, by forming a silicon oxide (SiO₂) film on the fabrication target film 1 of amorphous silicon (a-Si) in the CVD process.

The BARC 500 having a thickness of, for example, 30 nm is then formed on the hard mask HM10 as an antireflection film.

As shown in FIG. 3, the line-and-space resist mask RM10 having a half pitch HP10 of 45 nm is then formed on the BARC 500 by, for example, the ArF immersion exposure technique.

The BARC 500 and the hard mask HM10 of silicon oxide (SiO₂) are then fabricated by the RIE process using an etching gas such as carbon tetrafluoride (CF₄), haloform (CHF₃), or octafluoro-2-butene (C₄F₈). The resist RM10 and remaining films of the BARC 500 are then removed by the use of the oxygen (O₂) gas.

The hard mask HM10 of silicon oxide (SiO₂) is then slimmed by the use of a chemical such as a dilute hydrofluoric acid in the wet process in such a manner that the line width of the hard mask HM10 will be 15 nm. As a result, as shown in FIG. 4, the first pattern L10 having a line width W10 of 15 nm and a space width W20 of 75 nm is formed.

As shown in FIG. 5, a first sidewall film SW10 made of carbon is formed with a good coverage from the top of the first pattern L10 of silicon oxide (SiO₂) by the PE-CVD apparatus using a gas such as cyclopropane (C₃H₆) or ethylene (C₂H₄). The film formation temperature in this case is, for example, 300° C. to 500° C. The amount of carbon is previously adjusted in such a manner that the thickness of the first sidewall film SW10 will be W10 (=15 nm).

As shown in FIG. 11, the first sidewall film SW10 is then etched by an RIE process mainly using the oxygen (O₂) gas until the bottom of the first sidewall film SW10 in the narrow space completely falls out. As a result, as obvious from the comparison with FIG. 6, the top surface of the first sidewall film SW10 is lower than the top surface of the first pattern L10, and the first pattern L10 projects from the first sidewall film SW10.

As shown in FIG. 12, a second sidewall film SW30 is then formed from the tops of the first pattern L10 and the first sidewall film SW10. This is possible if silicon nitride (Si₃N₄) is formed with a good coverage by, for example, the ALD apparatus using disilane (Si₂H₄) and an ammonium (NH₄) gas. During the formation of silicon nitride (Si₃N₄), it is necessary to take into consideration a temperature and a plasma condition such that the first sidewall film SW10 is not damaged. For example, the film formation temperature is set at less than 500° C. The amount of silicon nitride (Si₃N₄) is set after previously adjusted in such a manner that the thickness of the second sidewall film SW30 will be 15 nm. In the present embodiment, silicon nitride (Si₃N₄) corresponds to, for example, a third material.

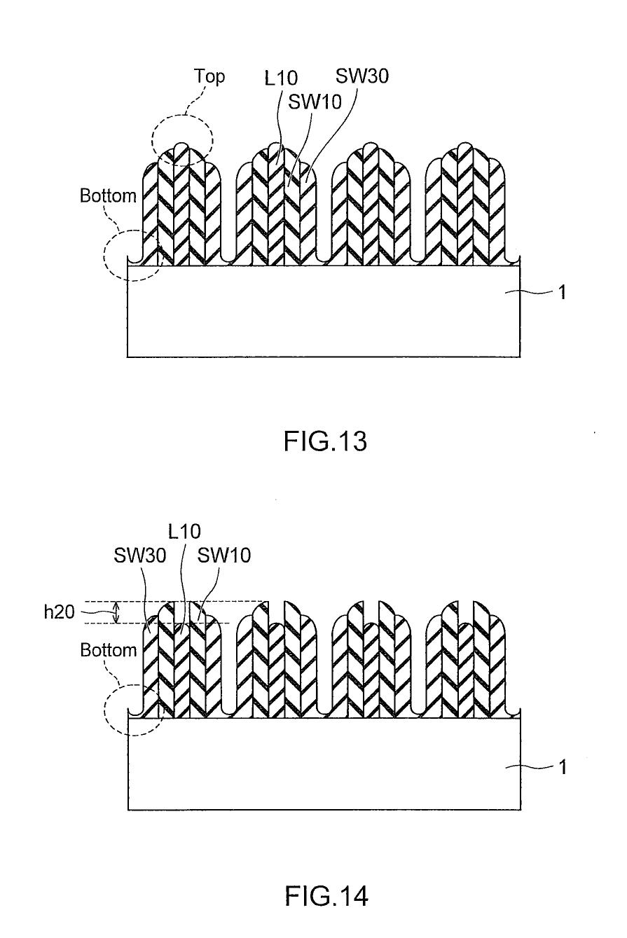

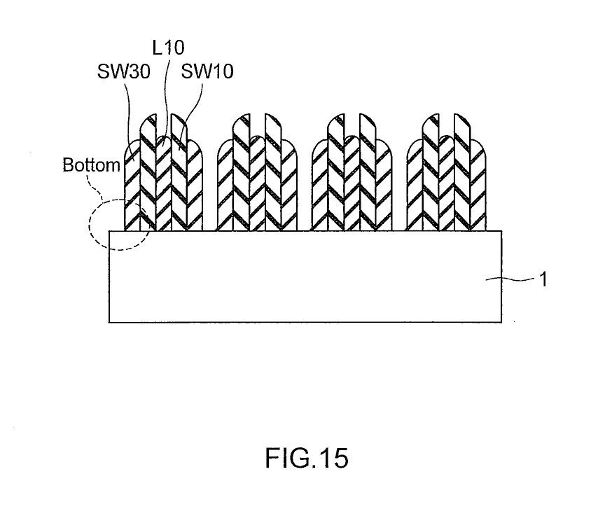

As shown in FIG. 13, the second sidewall film SW30 is then etched back by the RIE process using an etching gas such as difluoromethane (CH₂F₂) or fluoromethane (CH₃F). In this RIE process, there is a difference of etching rates between the top of the second sidewall film SW30 and the bottom of the narrow space. Therefore, as shown in FIG. 13, the etching gas is changed by the timing where the top first falls out and the tops of the first pattern L10 and the first sidewall film SW10 formed by carbon immediately thereunder are exposed. More specifically, the first pattern L10 can be selectively etched back, for example, by the use of the octafluoro-2-butene (C₄F₈) gas which allows for a selection ratio between the carbon material and silicon nitride (Si₃N₄) (FIG. 14). As a result, as shown in FIG. 14, the top surface of the first pattern L10 is lower than the top surface of the first sidewall film SW10 by a height h20. This height h20 is a height necessary to obtain the same height as the height of the later-described second sidewall film SW30 in a finished shape. After the height is reduced as required in such a manner that the height will be the same in the end, etchback is again performed by the use of an etching gas such as difluoromethane (CH₂F₂) or fluoromethane (CH₃F), and etching is performed until the bottom in the narrow space completely falls out as shown in FIG. 15.

Finally, the first sidewall film SW10 is removed by, for example, ashing using an oxygen (O₂) gas, then the mask pattern MP10 shown in FIG. 1 and FIG. 2 is obtained.

Thus, according to the manufacturing method of the mask pattern in the present embodiment as well, the first sidewall film SW10 is used as a sacrifice film to form the mask pattern by the first pattern L10 and the second sidewall film SW30, so that the line-and-space silicon oxide (SiO₂) hard mask with an HP of 15 nm is provided.

The manufacturing method of the mask pattern in the present embodiment includes the process of lowering the first pattern L10 by the height h20 corresponding to the difference between the height of the first pattern L10 and the height of the second sidewall film SW30 resulting from the etchback during the formation of the second sidewall film SW30. Thus, the difference between the height of the first pattern L10 and the height of the second sidewall film SW30 has been already adjusted, so that a mask pattern in which the variation of height between the first pattern L10 and the second sidewall film SW30 is small is provided. Consequently, by fabricating a foundation fabrication target film with the use of such a mask pattern, it is possible to form a satisfactory pattern without causing dimensional variation.

### (2) Embodiment 2

### (a) Mask Pattern

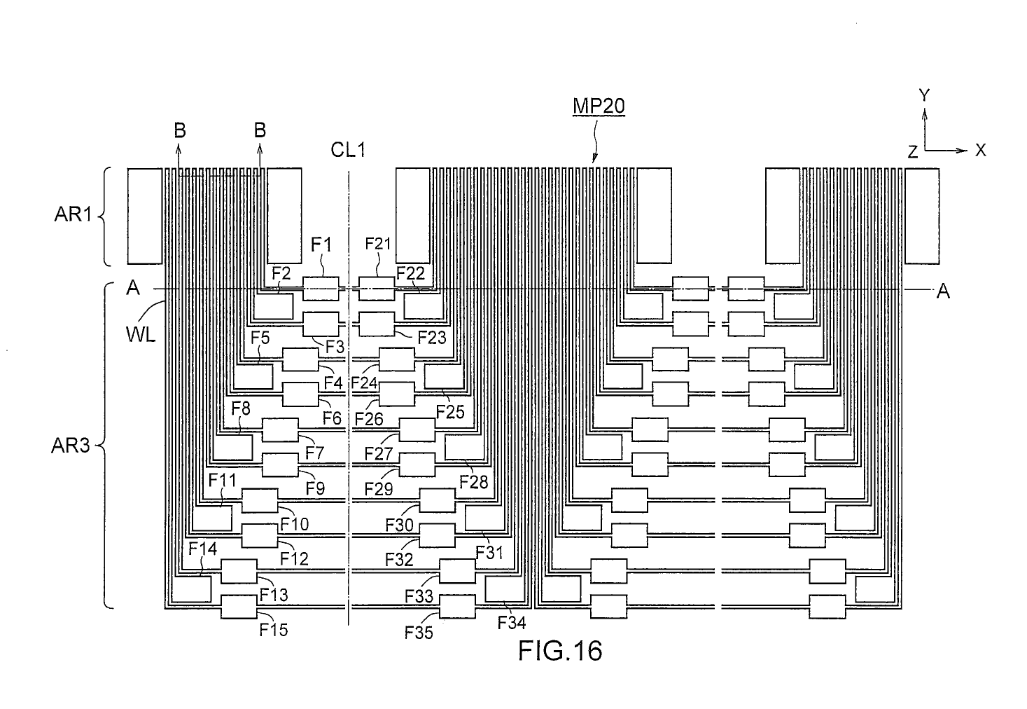

FIG. 16 is a plan view showing an example of a mask pattern according to Embodiment 2.

A mask pattern MP20 according to the present embodiment is an example of a mask pattern to form a semiconductor memory device such as a nonvolatile memory.

As shown in FIG. 16, the mask pattern MP20 includes a first area AR1 and a second area AR3. The first area AR1 is an area to form a memory cell and a select gate SG. A sectional view taken along the line B-B in FIG. 16 is similar to that in FIG. 2.

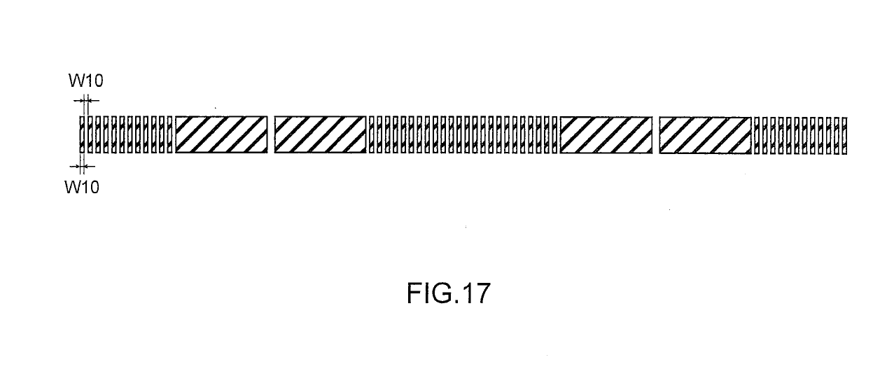

The second area AR3 is a lead-out area of a word line or a bit line. FIG. 17 is an exemplary sectional view taken along the line A-A in FIG. 16. Although a mask pattern of a word line WL is described below as an example of a mask pattern of a leader line from the memory cell, the word line WL is applicable to the bit line as it is in accordance with the designs and modes of peripheral circuits. This also applies to a mask pattern according to Embodiment 3 described later.

In the mask pattern MP20 shown in FIG. 16, of two terminals of a word line WL pattern extending in the Y-direction, the terminal opposite to a line pattern (see FIG. 1 and FIG. 2) of the memory cell is connected to rectangular fringes F1 to F15 and F21 to F34. The fringes F1 to F15 and F21 to F34 are mask patterns for hook-up electrodes, and are greater in width than the word line WL in both the X-direction and the Y-direction.

As shown in FIG. 16, in the mask pattern MP20 according to the present embodiment, the fringes are line-symmetrically arranged in such a manner that three fringes constitute one unit. If the fringes F1 to F3 and F21 to F23 are described by way of example, two units of the fringes are line-symmetrically arranged with respect to a straight line CL1. In the present embodiment, the distance between the units facing each other increases from the side of the first area AR1 toward the peripheral edge.

### (b) Manufacturing Method

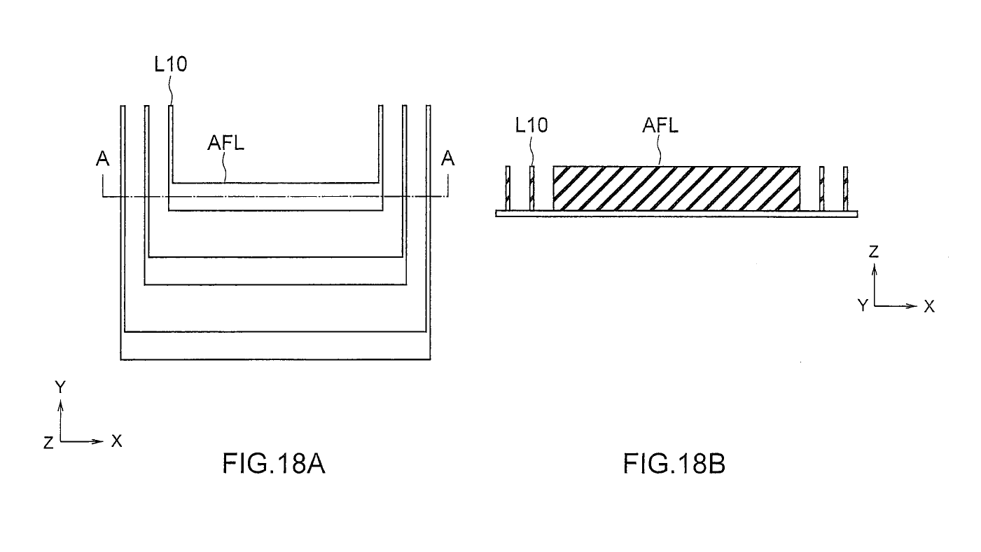

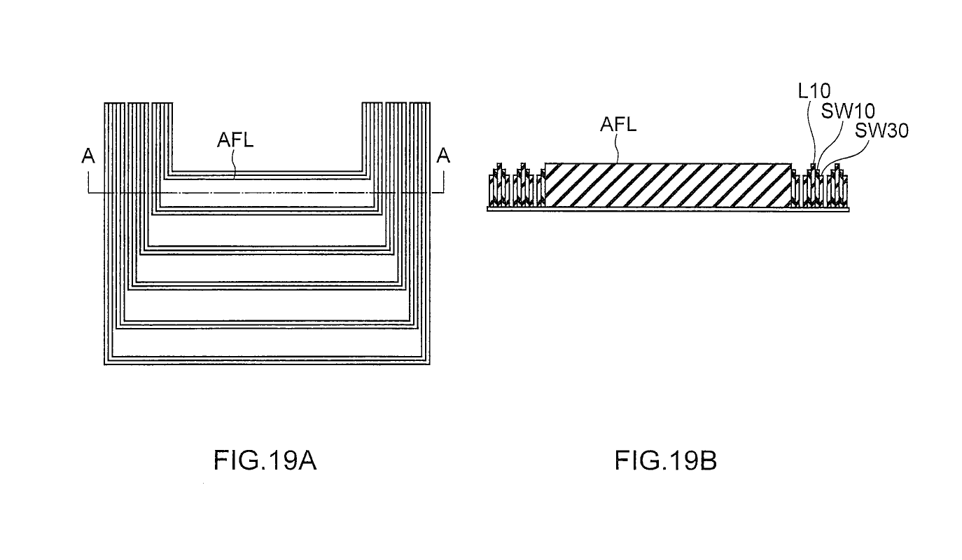

A manufacturing method of the mask pattern MP20 shown in FIG. 16 is described below with reference to FIG. 3 to FIG. 5, FIG. 11 to FIG. 15, and FIG. 18A to FIG. 26. FIG. 18A and FIG. 18B are an exemplary plan view and an exemplary sectional view respectively showing manufacturing processes of a part corresponding to the line A-A in FIG. 16. FIG. 19A to FIG. 23 are exemplary plan views and sectional views each showing a process that follows a process shown in the drawing having a number lower by one.

In the present embodiment as well, a target half pitch dimension in a finished state is 15 nm.

First, a first pattern L10 is formed on a fabrication target film 1.

More specifically, the first hard mask HM10 (see FIG. 3) is formed, for example, by forming a silicon oxide (SiO₂) film on the fabrication target film 1 (see FIG. 3) of amorphous silicon (a-Si) in a CVD process. A BARC 500 (see FIG. 3) having a thickness of, for example, 30 nm is then formed on the hard mask HM10 as an antireflection film. As shown in FIG. 3, a line-and-space resist mask RM10 having a half pitch HP10 of 45 nm is then formed on the BARC 500 by a lithography process using, for example, the ArF immersion exposure technique.

The BARC 500 and the hard mask HM10 of silicon oxide (SiO₂) are then fabricated by an RIE process using an etching gas such as carbon tetrafluoride (CF₄), haloform (CHF₃), or octafluoro-2-butene (C₄F₈). A resist RM10 and remaining films of the BARC 500 are then removed by the use of an oxygen (O₂) gas.

The hard mask HM10 of silicon oxide (SiO₂) is then slimmed by the use of a chemical such as a dilute hydrofluoric acid in a wet process in such a manner that the line width of the hard mask HM10 will be 15 nm. As a result, as shown in FIG. 4, the first pattern L10 having a line width W10 of 15 nm and a space width W20 of 75 nm is formed.

In this case, in the second area AR3, part of the end of the first pattern L10 is formed into a shape AFL like joined flags to allow for a great line-to-line distance as shown in FIG. 18A and FIG. 18B. This joined-flag shape AFL serves to form a hook-up electrode of the word line WL in the end as shown in FIG. 16.

As shown in FIG. 5, a first sidewall film SW10 made of carbon is formed with a good coverage from the top of the first pattern L10 of silicon oxide (SiO₂) by the PE-CVD apparatus using a gas such as cyclopropane (C₃H₆) or ethylene (C₂H₄). The film formation temperature in this case is, for example, 300° C. to 500° C. The amount of carbon is previously adjusted in such a manner that the thickness of the first sidewall film SW10 will be W10 (=15 nm).

As shown in FIG. 11, the first sidewall film SW10 is then etched by an RIE process mainly using the oxygen (O₂) gas until the bottom of the first sidewall film SW10 in the narrow space completely falls out.

As shown in FIG. 12, a second sidewall film SW30 is then formed from the tops of the first pattern L10 and the first sidewall film SW10. This is possible if silicon nitride (Si₃N₄) is formed with a good coverage by, for example, the ALD apparatus using disilane (Si₂H₄) and an ammonium (NH₄) gas. During the formation of silicon nitride (Si₃N₄), it is necessary to take into consideration a temperature and a plasma condition such that the first sidewall film SW10 is not damaged. For example, the film formation temperature is set at less than 500° C. The amount of silicon nitride (Si₃N₄) is set after previously adjusted in such a manner that the thickness of the sidewall of the second sidewall film SW30 will be 15 nm.

As shown in FIG. 19A and FIG. 19B, the second sidewall film SW30 is then etched by the RIE process using an etching gas such as difluoromethane (CH₂F₂) or fluoromethane (CH₃F) until the bottom of the second sidewall film SW30 completely falls out.

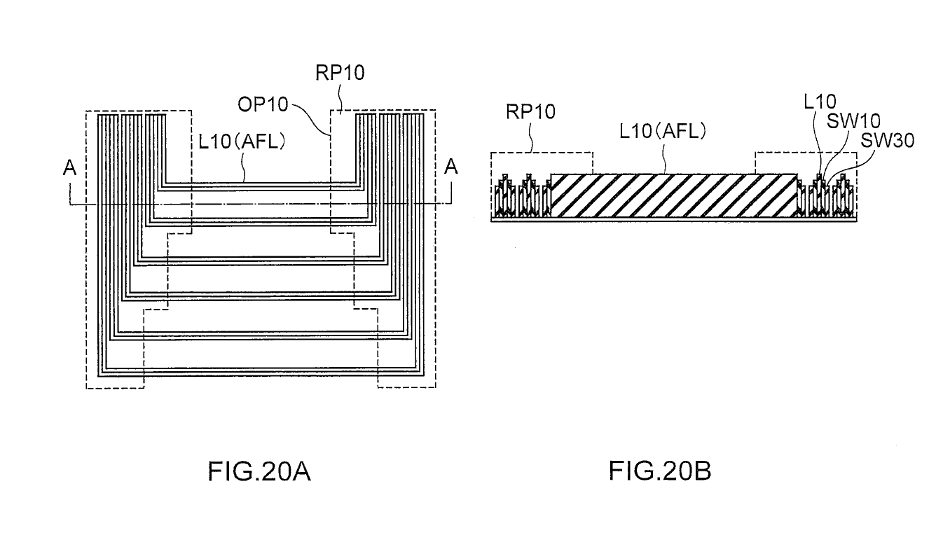

As shown in FIG. 20A and FIG. 20B, a resist pattern RP10 having an opening OP10 which allows part of the first pattern L10 alone to be partly removed is then formed in the joined-flag shape AFL. The resist pattern RP10 can be formed by resist drawing from the tops of the first pattern L10, the first sidewall film SW10, and the second sidewall film SW30 in a second lithography process.

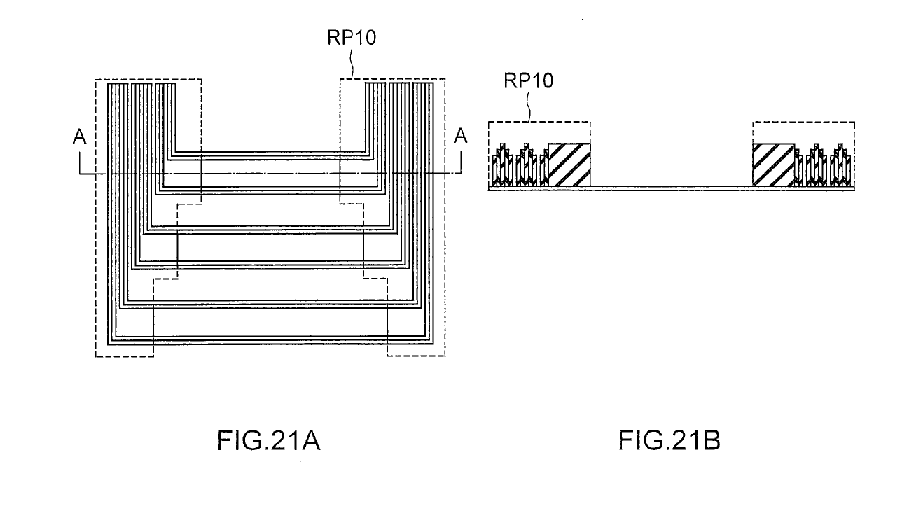

As shown in FIG. 21A and FIG. 21B, the first pattern L10 in the opening OP10 of the resist pattern RP10 is then only removed by performing a wet process such as a dilute hydrofluoric acid treatment.

The resist pattern RP10 and the first sidewall film SW10 are then removed by RIE. During the removal process, RIE is added to selectively reduce the height of the first pattern L10 alone.

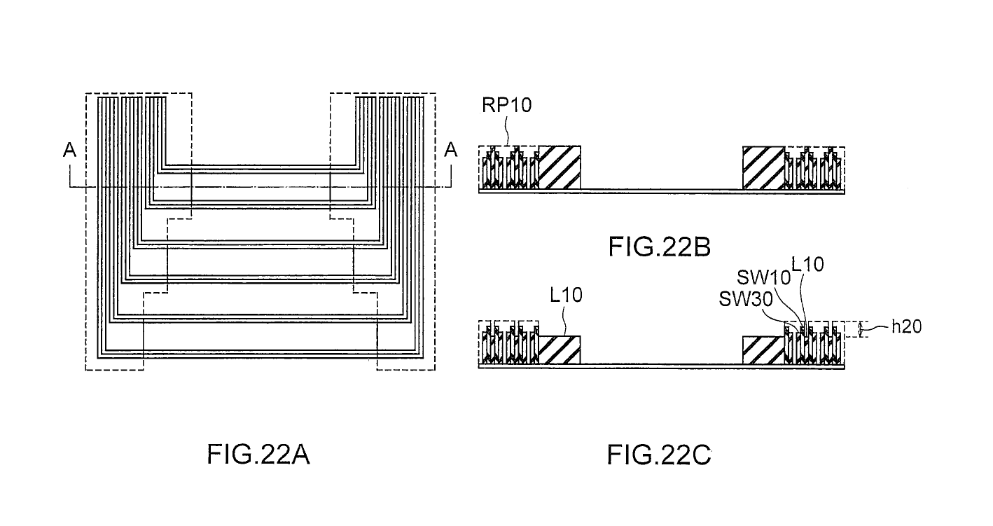

In a specific RIE process, the whole resist pattern RP10 is first etched back flatly by the oxygen (O₂) gas, and the etching gas is changed by the timing where the top of the tallest first pattern L10 is exposed as shown in FIG. 22A and FIG. 22B. More specifically, the first pattern L10 can be selectively etched back, for example, by the use of the octafluoro-2-butene (C₄F₈) gas which allows for a selection ratio between the carbon material and silicon nitride (Si₃N₄). As a result, as shown in FIG. 22C, the top surface of the first pattern L10 is lower than the top surface of the first sidewall film SW10 by a height h20. This height h20 is a height necessary to obtain the same height as the height of the second sidewall film SW30 in a finished shape.

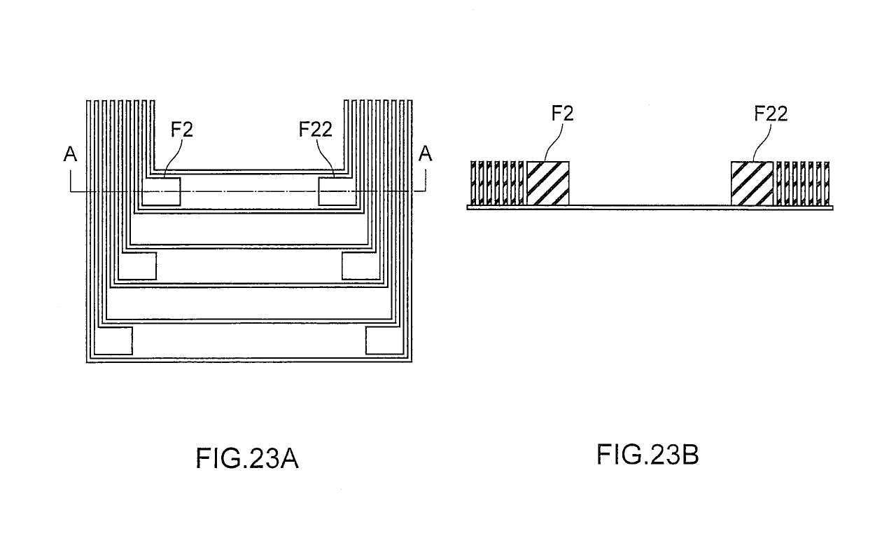

As shown in FIG. 23A and FIG. 23B, the resist pattern RP10 and the first sidewall film SW10 are then completely removed by the oxygen (O₂) gas again.

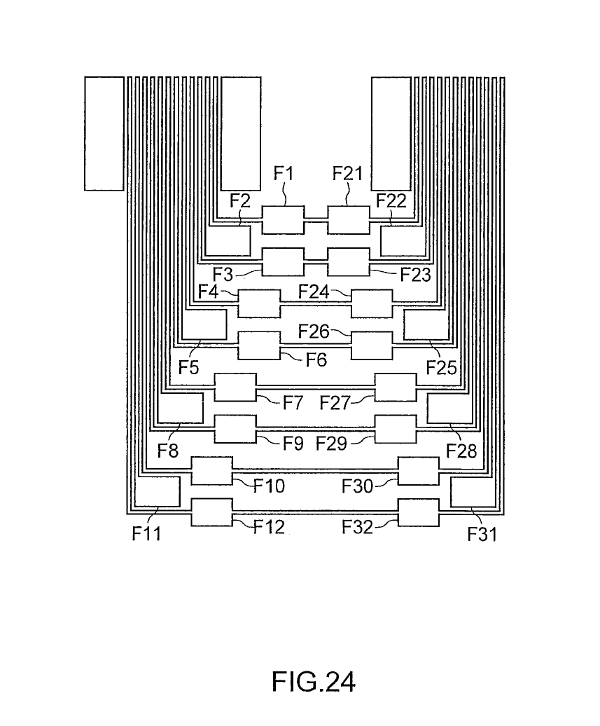

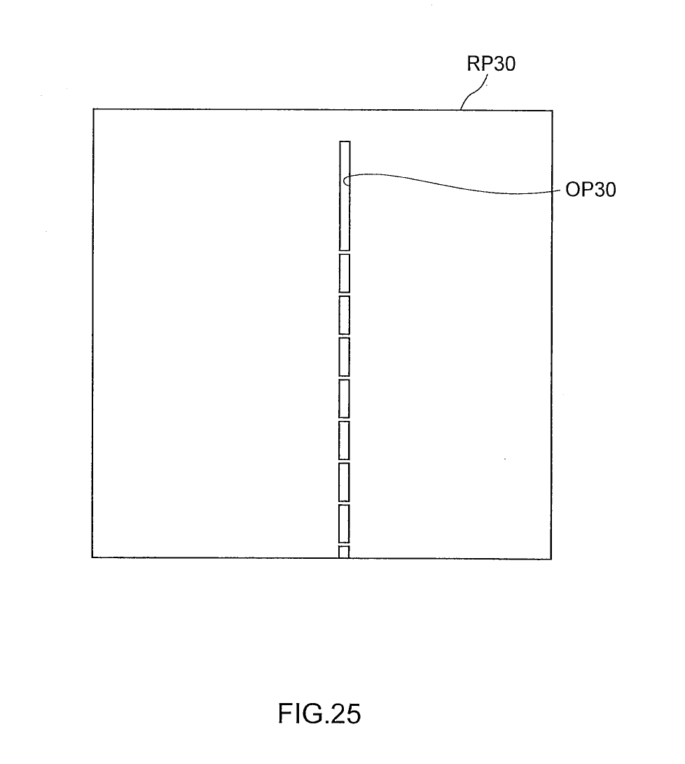

A mask pattern of the fringes F1, F21, F3, F23 . . . connected to the word lines surrounding the fringes F2, F22 . . . are then formed by an exposure treatment as shown in FIG. 24A, and etched by the use of a resist pattern RP30 in which an opening is provided in the center of the units of the opposite fringes as shown in FIG. 25. Consequently, the mask pattern MP20 shown in FIG. 16 is provided.

According to the manufacturing method of the mask pattern in the present embodiment, a hard mask of silicon oxide (SiO₂) composed of the first pattern L10 and the second sidewall film SW30 and including a line-and-space in which both the line width and the space width are W10 (=15 nm) is formed. The difference between the height of the first pattern L10 and the height of the second sidewall film SW30 has been already adjusted, so that a mask pattern in which the variation of height between the first pattern L10 and the second sidewall film SW30 is small is provided. Consequently, by fabricating a foundation fabrication target film with the use of such a mask pattern, it is possible to form a satisfactory pattern without causing dimensional variation.

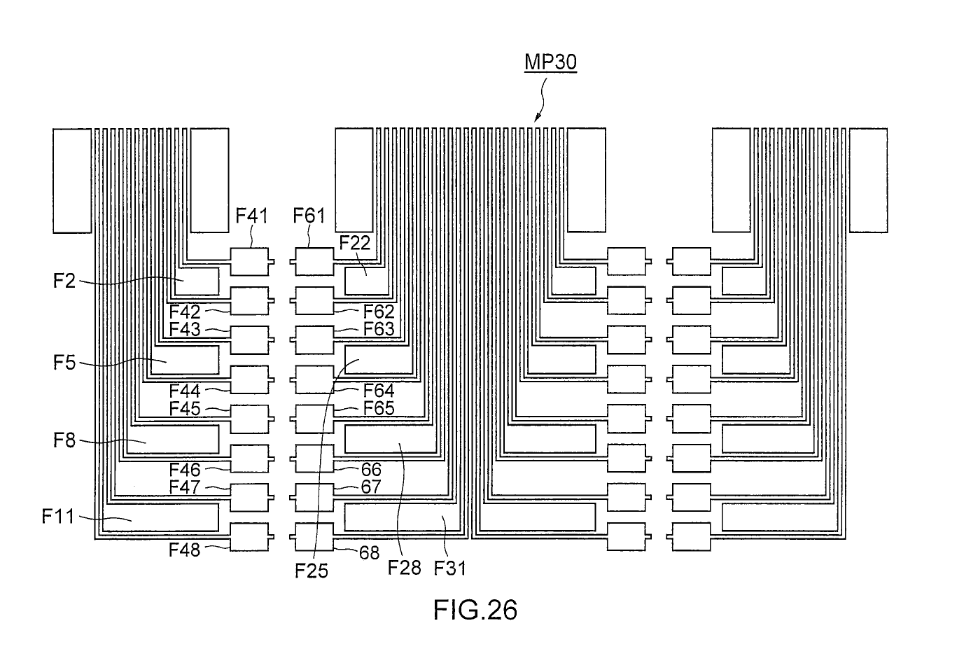

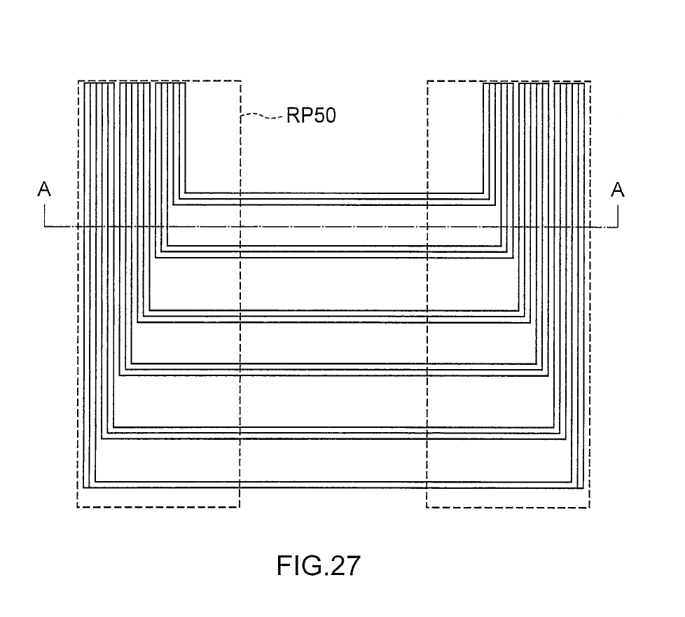

Although the distance between the fringe units facing each other increases from the side of the first area AR1 toward the peripheral edge in the aspect described by way of example according to the embodiment, this is not at all a limitation. For example, the distance between the fringe units facing each other may be constant as shown in FIG. 26. This mask pattern MP30 can be easily formed by the use of a resist pattern RP50 having a rectangular opening, for example, as shown in FIG. 27.

In the aspect described by way of example according to the embodiment, a shape like joined flags is formed as the shape of the end of the first pattern L10 for forming the hook-up electrode of the word line (WL) in the end, and is divided into flag shapes by the subsequent etching using a resist. However, the shape of the end of the first pattern L10 is not limited to this. For example, the flag shape may be formed from the beginning.

### (3) Embodiment 3

### (a) Mask Pattern

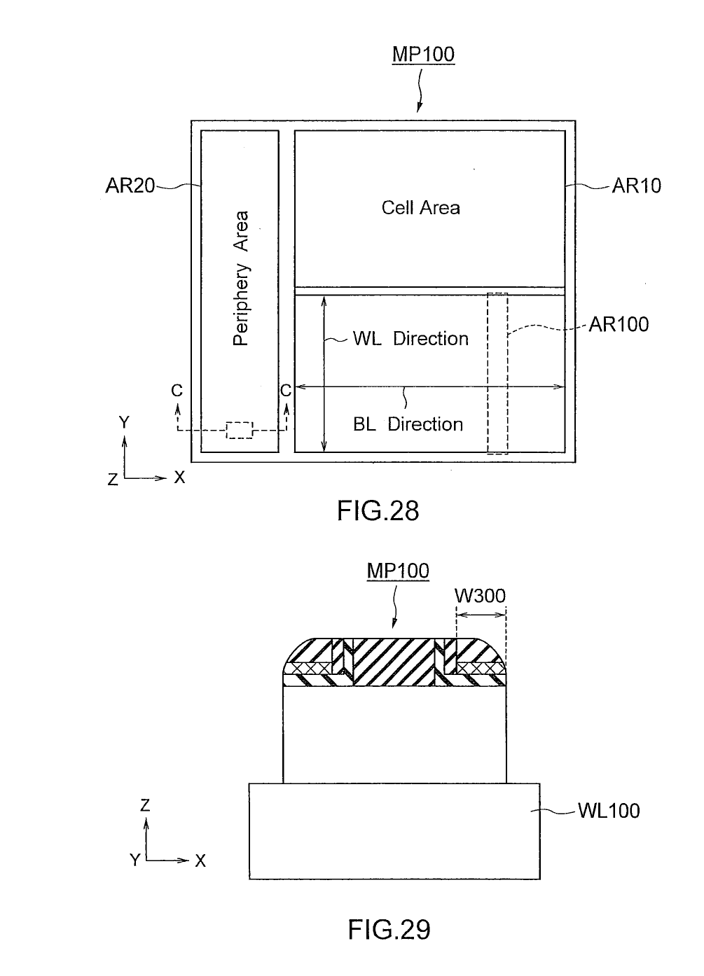

FIG. 28 is a plan view schematically showing the general configuration of a mask pattern MP100 according to Embodiment 3. The mask pattern MP100 according to the present embodiment is a mask pattern provided on a fabrication target film WL100 (see FIG. 29) to form a nonvolatile semiconductor memory device, and includes a cell area AR10 and a peripheral circuit area AR20.

Transistors of peripheral circuits are formed in the peripheral circuit area AR20. An exemplary sectional view taken along the line C-C parallel to a bit line direction (X-direction in FIG. 28) in the part of the peripheral circuit area AR20 of the mask pattern MP100 is shown in FIG. 29.

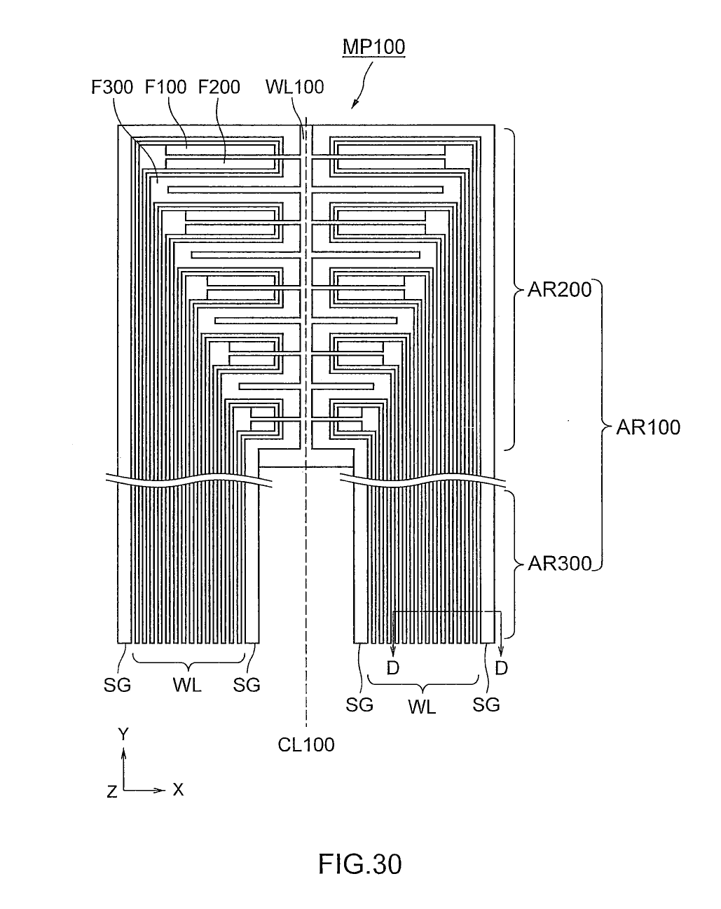

FIG. 30 shows an exemplary plan view of the mask pattern MP100 in a partial area AR100 in the cell area AR10. The area AR100 includes a memory cell array area AR300, and a lead-out area AR200 for word lines in a memory cell array.

The mask pattern MP100 according to the present embodiment is configured in such a manner that mask patterns corresponding to a plurality of word lines WL are surrounded by mask patterns of two select gate lines SG to form one block in the lead-out area AR200. In the exemplary plan view shown in FIG. 30, 12 word lines WL are surrounded by two select gate lines SG to form one block.

In the present embodiment, the number N of mask patterns of the word lines WL is provided by

N=2+(n−1)×3 (Equation 1)

wherein n is the number of first patterns (core materials) to be sacrifice films in a manufacturing method described later.

The mask patterns corresponding to the respective word lines WL are connected to fringes F100, F200, and F300 which are greater in width in the X-direction and the Y-direction than the word lines WL at the terminal opposite to the memory cell array area AR300. The fringes F100, F200, and F300 are mask patterns for hook-up electrodes.

Each block is disposed line-symmetrically to adjacent block with respect to a line CL100 parallel to the word lines. The fringes F100, F200, and F300 as one unit are repetitively arranged in the Y-direction in one block, and are line-symmetrically arranged in the adjacent blocks with respect to the line CL100.

In the example shown in FIG. 30, the distance between the fringes F100, F200, and F300 in the adjacent blocks is constant, and the fringes F100, F200, and F300 increase in width in the X-direction toward the terminal in the same block.

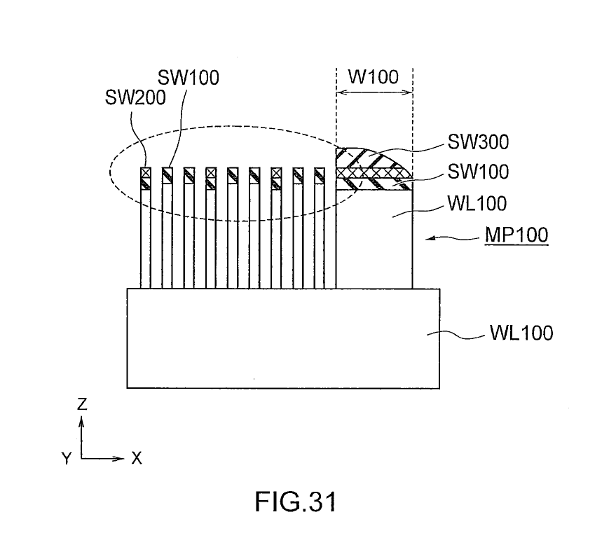

An exemplary sectional view taken along the line D-D parallel to the bit line direction (X-direction) of the mask pattern MP100 in the memory cell array area AR300 is shown in FIG. 31.

In the mask pattern MP100 shown in FIG. 31, SW100 which are mask pattern portions to form the word lines WL have almost no variation in the height of their tops. Thus, it is possible to form a satisfactory pattern without dimensional variation as a result of the fabrication of the fabrication target film WL100 using the mask pattern MP100.

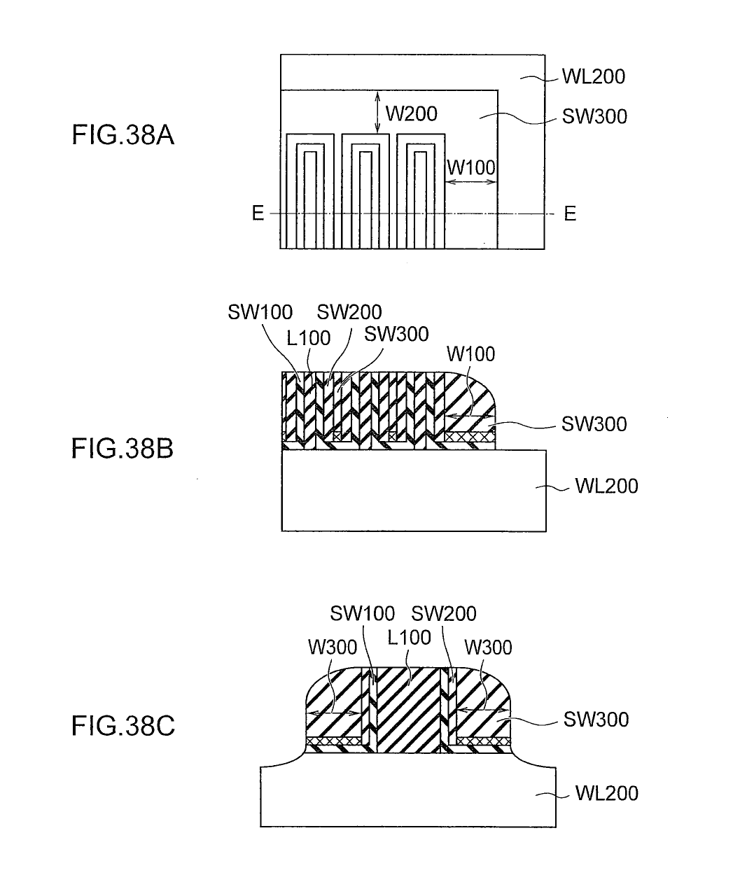

The width W100 of the end of the memory cell array in the bit line direction (X-direction), that is, the width W100 of a select gate SG is the same as the width W200 (see FIG. 38A) of the end in the word line direction (Y-direction), and is also the same as the spacer width W300 in the X-direction in the peripheral circuit area AR20.

(b) Manufacturing Method

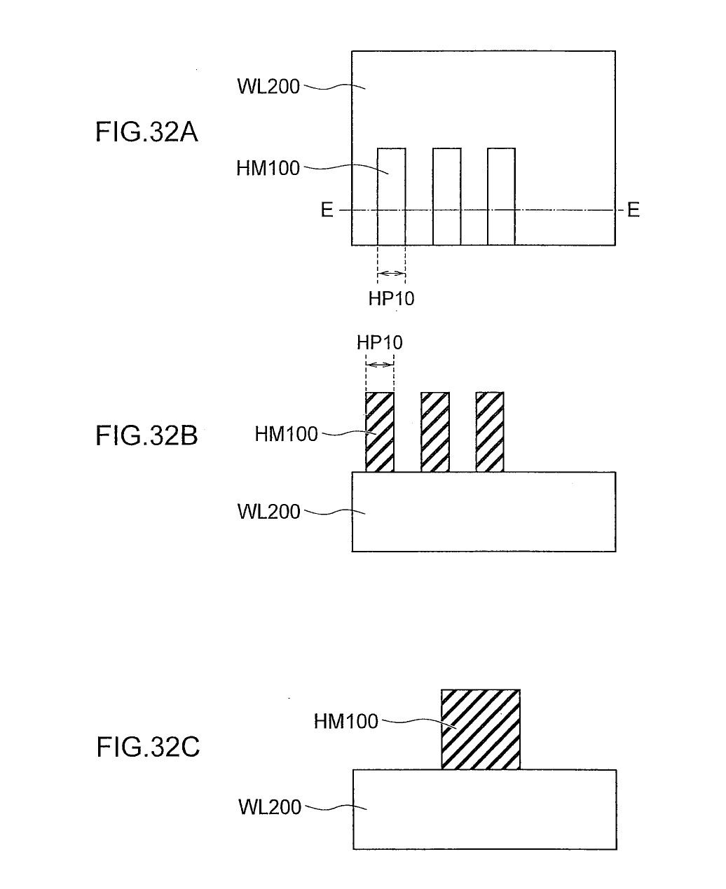

A manufacturing method of the mask pattern MP100 shown in FIG. 28 to FIG. 31 is described with reference to FIG. 32A to FIG. 50.

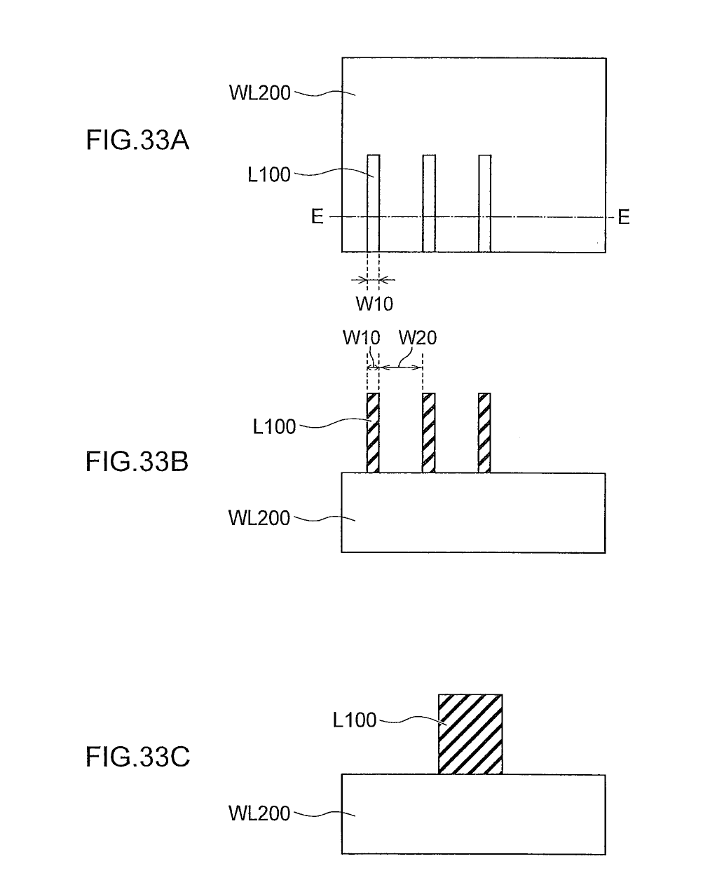

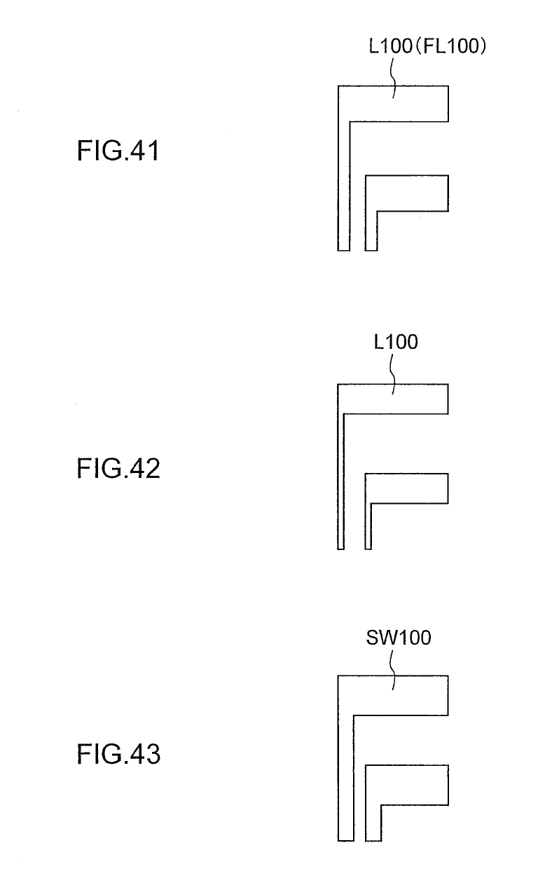

FIG. 32A is an exemplary process plan view corresponding to a partial enlarged view of the part along the line D-D in FIG. 30 in the mask pattern MP100 in the memory cell array area AR300. FIG. 32B is an exemplary sectional view taken along the line E-E in FIG. 32A. FIG. 32C is an exemplary process sectional view corresponding to the process shown in FIG. 32A and FIG. 32B, and is a process sectional view corresponding to the part along the line C-C in FIG. 28. FIG. 33A to FIG. 40C are diagrams each showing a process that follows a process shown in the drawing having a number lower by one. FIG. 41 to FIG. 50 are process plan views showing some of the manufacturing processes of the mask pattern MP100 in the peripheral circuit area AR20.

First, a first pattern (core material) L100 is formed on a fabrication target film WL200.

More specifically, a hard mask HM100 (see FIG. 32B) is formed, for example, by forming a silicon oxide (SiO₂) film on the fabrication target film WL200 (see FIG. 32B) of amorphous silicon (a-Si) in a CVD process. An antireflection film (not shown) is then formed on the hard mask HM100. On this antireflection film, a line-and-space resist mask having a half pitch HP10 of 45 nm is formed by a first lithography process. The BARC and the silicon oxide (SiO₂) hard mask HM100 are fabricated by an RIE process. In the present embodiment, silicon oxide (SiO₂) corresponds to, for example, a first material.

Thus, as shown in FIG. 32A and FIG. 32B, the silicon oxide (SiO₂) hard mask HM100 including a line-and-space pattern having a half pitch HP10 of 45 nm is formed in the memory cell array area AR300. At the same time, a pattern shown in FIG. 32C is formed in the peripheral circuit area AR20, and a word-line-pattern-compatible pattern having a rectangular fringe pattern FL100 at the terminal as shown in FIG. 41 is formed in the lead-out area AR200. Although not specifically shown, another fabrication target film WL100 (see FIG. 29 and FIG. 31) is formed immediately under the fabrication target film WL200.

The resist and remaining films of the antireflection film are then removed.

The silicon oxide (SiO₂) hard mask HM100 is then slimmed in such a manner that the line width thereof will be 15 nm. As a result, as shown in FIG. 33A and FIG. 33B and in FIG. 42, the first pattern L100 having a line width W10 of 15 nm and a space width W20 of 75 nm is formed. At the same time, as shown in FIG. 33C, the pattern is slimmed in the peripheral circuit area AR20 as well.

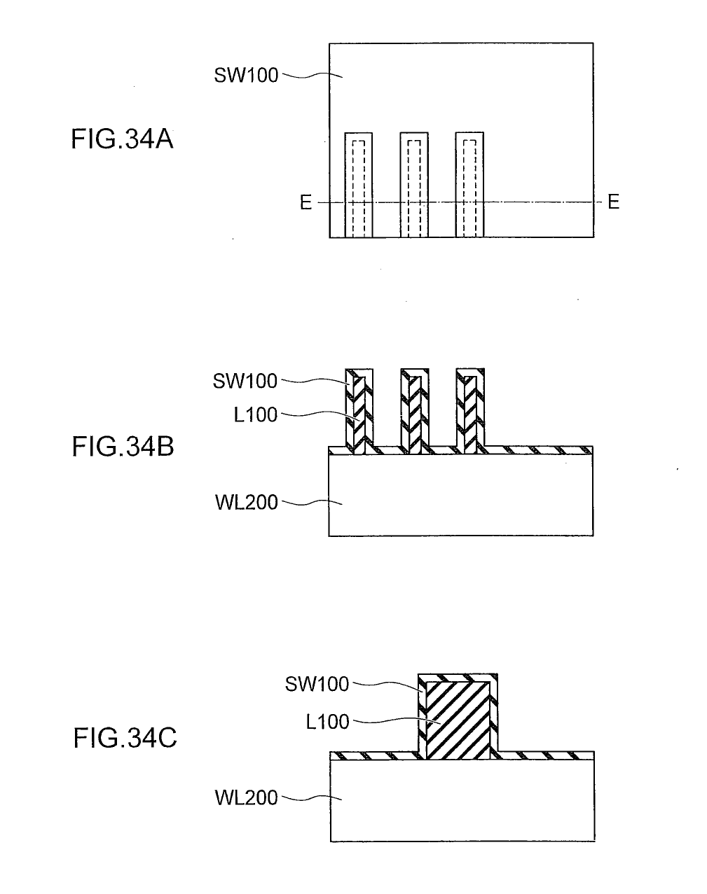

As shown in FIG. 34A to FIG. 34C and in FIG. 43, the first sidewall film SW100 is then formed from the top of the first pattern L100 of silicon oxide (SiO₂). This is possible if silicon nitride (Si₃N₄) is formed with a good coverage by, for example, the ALD apparatus using disilane (Si₂H₄) and an ammonia (NH₃) gas. The amount of silicon nitride (Si₃N₄) is set after previously adjusted in such a manner that the thickness of the sidewall of the first sidewall film SW100 will be 15 nm. In the present embodiment, silicon nitride (Si₃N₄) corresponds to, for example, a second material.

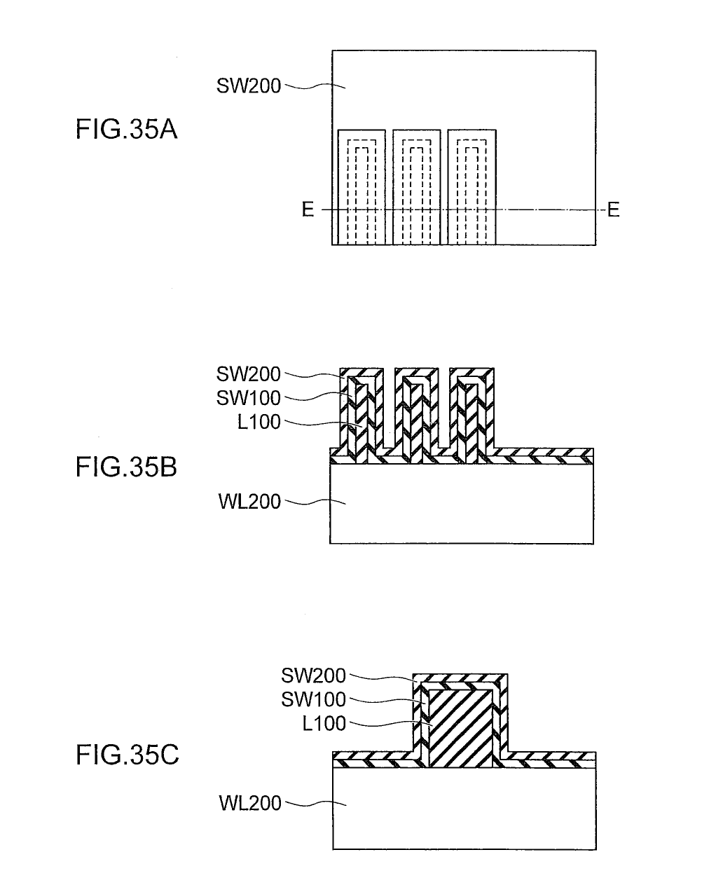

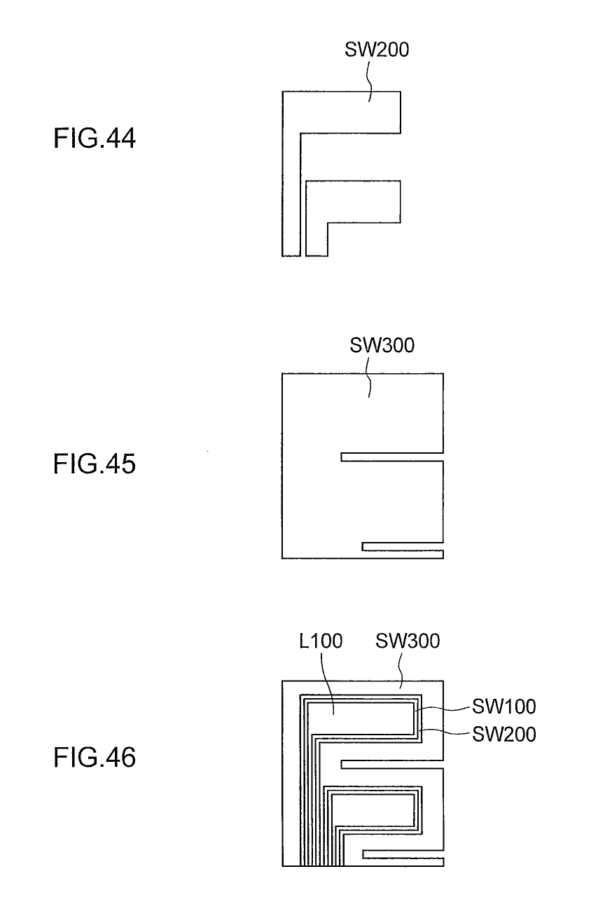

As shown in FIG. 35A to FIG. 35C and in FIG. 44, a second sidewall film SW200 is then formed by forming a silicon oxide (SiO₂) film on the first sidewall film SW100. This is possible if silicon oxide (SiO₂) is formed with a good coverage by, for example, the ALD apparatus using trisdimethylaminosilane (His [N(CH₃)₂]₃) and an ozone (O₃) gas. In the present embodiment, silicon oxide (SiO₂) corresponds to, for example, a third material.

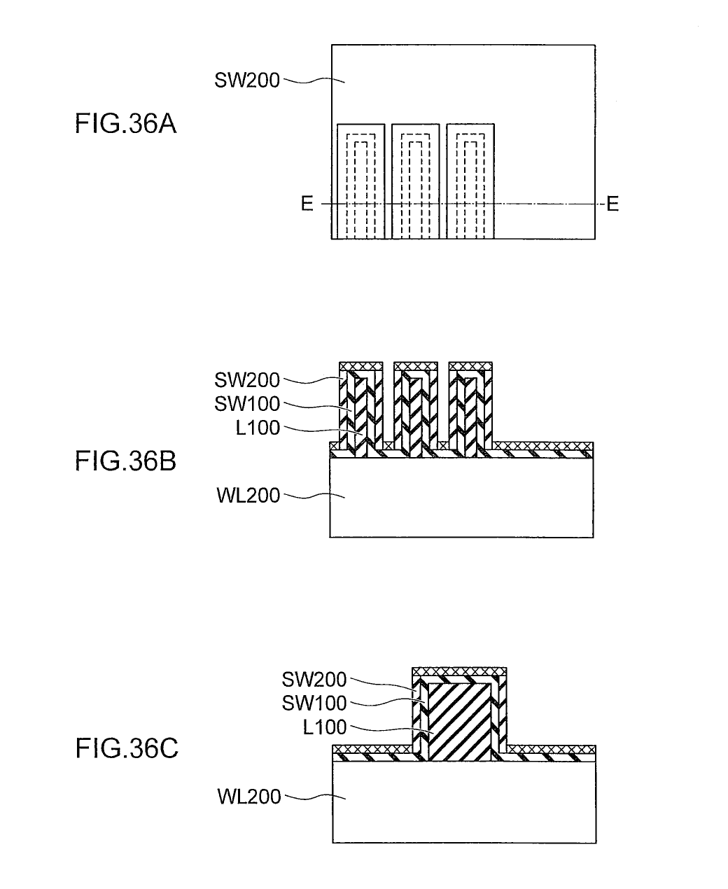

An N-type impurity is then implanted into the second sidewall film SW200. Thus, as shown by hatching in FIG. 36B and FIG. 36C, the top and bottom of the second sidewall film SW200 are transformed into SiON, so that the resistance of silicon oxide (SiO₂) to etching improves, and the bottom of the second sidewall film SW200 remains unremoved when the first pattern L100 and the first sidewall film SW100 are removed later to form a mask pattern.

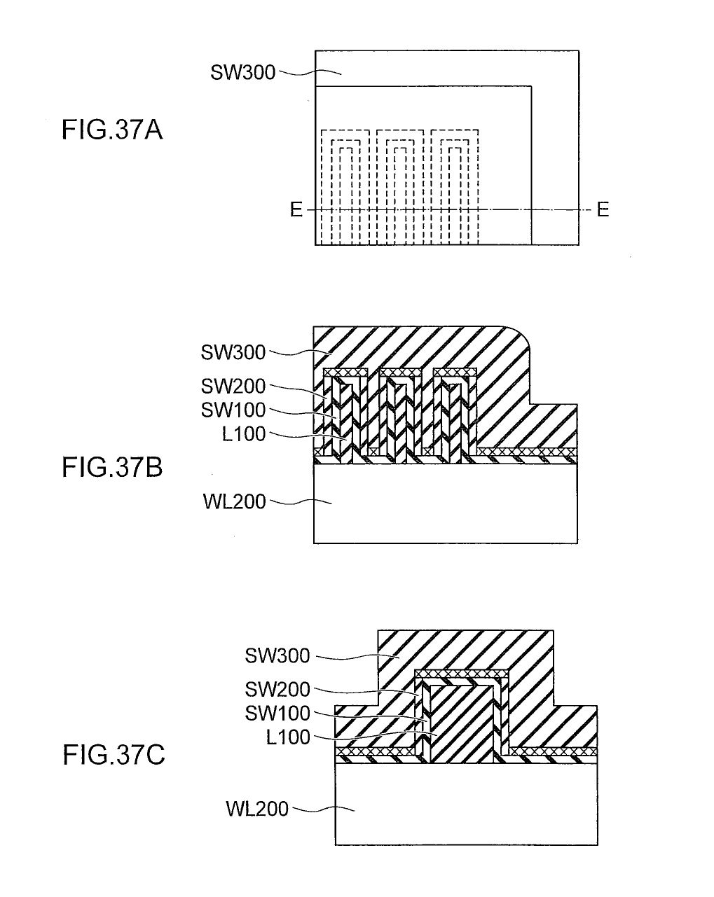

As shown in FIG. 37A to FIG. 37C and in FIG. 45, a silicon nitride (Si₃N₄) film SW300 is formed on the entire surface, for example, by a low pressure (LP)-CVD apparatus or ALD apparatus using dichlorosilane (SiH₂Cl₂), disilane (Si₂H₄), and an ammonium (NH₄) gas. By adjusting the formation amount of the silicon nitride (Si₃N₄) film SW300 at the same time, it is possible to determine the dimension (the sign W200 in FIG. 38A) of the end of the memory cell array area AR300 (in the word line WL direction), the width (the sign W100 in FIG. 38B) of the select gate SG, and a spacer dimension (the sign W300 in FIG. 38C) in the bit line BL direction in a peripheral transistor in the peripheral circuit area AR20. In the present embodiment, silicon nitride (Si₃N₄) corresponds to, for example, a fourth material.

As shown in FIG. 38A to FIG. 38C and in FIG. 46, the silicon nitride (Si₃N₄) SW300, the top of the second sidewall film SW200 transformed into SiON, and the first sidewall film SW100 are then etched and removed by collective fabrication until the top of the first sidewall film SW100 is exposed.

As a result, the dimension W100 of the end of the memory cell array area AR300 (in the word line WL direction), the width W200 of the select gate SG, and the spacer dimension W300 in the bit line BL direction in the peripheral transistor in the peripheral circuit area AR20 become the same.

If the top surface of the first sidewall film SW100 and the top surface of the silicon nitride (Si₃N₄) film SW300 are formed into a uniform height in this case, height variation of the mask patterns is eliminated, and a satisfactory pattern having a little dimensional variation can be obtained during the fabrication of the fabrication target film WL200.

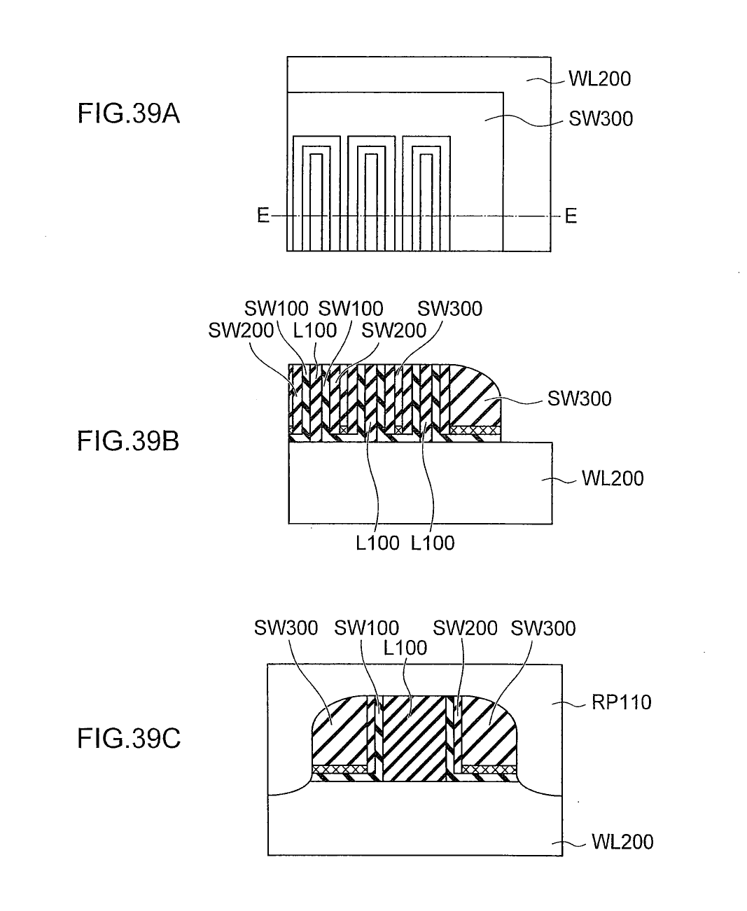

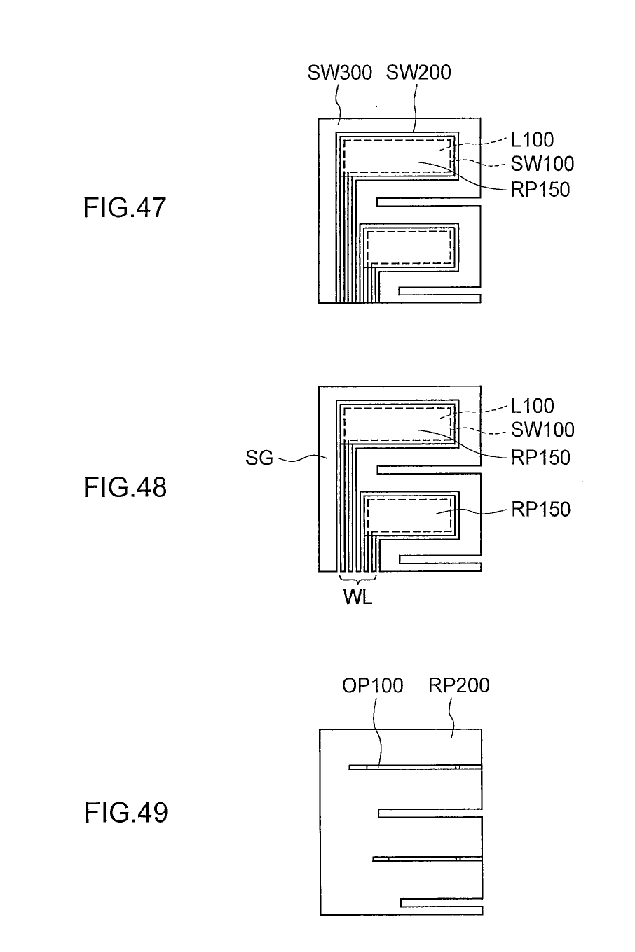

As shown in FIG. 39A to FIG. 39C, resist patterns RP110 and RP150 are then respectively formed in the peripheral circuit area AR20 and the lead-out area AR200 alone by patterning using a photoresist. When used to form word lines, the resist pattern RP150 is formed over the L100 and the SW100 in a lead-out portion as shown in FIG. 47 to ensure the area of a word line lead-out portion that allows for contact.

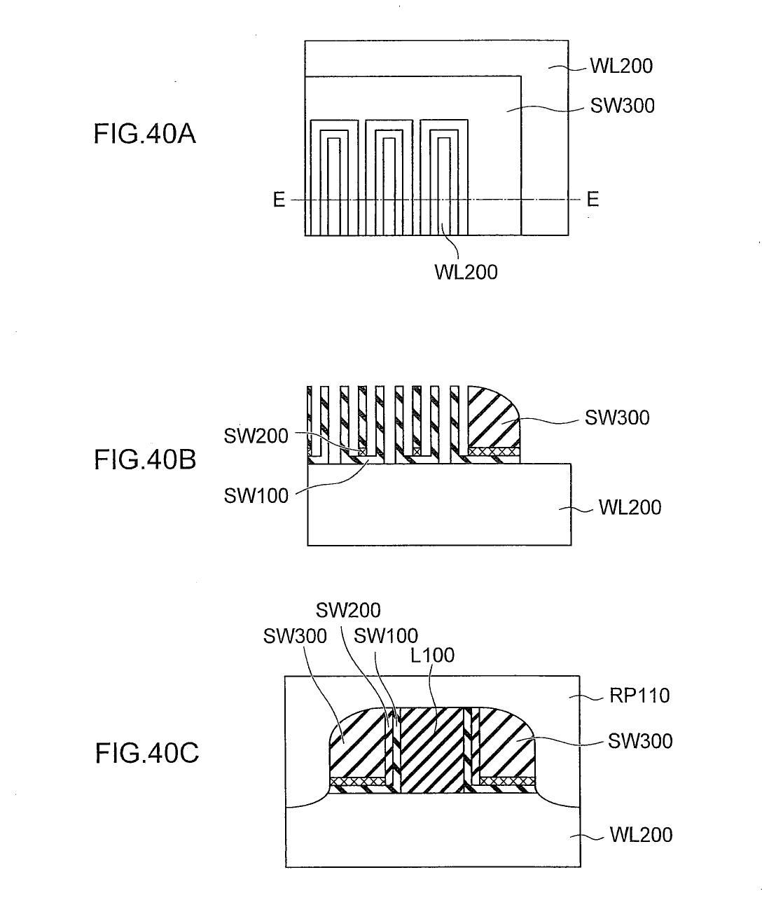

The first pattern L100 and the second sidewall film SW200 alone are then selectively removed by etching in a wet process such as a dilute hydrofluoric acid treatment or in a dry chemical process using an etching gas such as nitrogen trifluoride (NF₃) or ammonia (NH₃). In this case, as described above, the bottom of the second sidewall film SW200 transformed into SiON has improved in etching resistance to silicon oxide (SiO₂), and therefore remains unremoved. As a result, as shown in FIG. 40A and FIG. 40B, in the memory cell array area AR300, the first sidewall film SW100, the bottom of the second sidewall film SW200 transformed into SiON, and the silicon nitride (Si₃N₄) film SW300 formed on the bottom of the second sidewall film SW200 remain and serve as mask patterns.

In this case, the end of the memory cell array area AR300 (in the word line WL direction) and the select gate SG are simultaneously formed.

As shown in FIG. 48, a mask pattern of the select gate SG and the word lines WL is formed in the lead-out area AR200. However, in the peripheral circuit area AR20, the first pattern L100 and the second sidewall film SW200 are protected by the resist pattern RP110 and are therefore not removed. Similarly, in the fringe in the lead-out area AR200, the first pattern L100 and the first sidewall film SW100 are protected by the resist pattern RP150 and are therefore not removed.

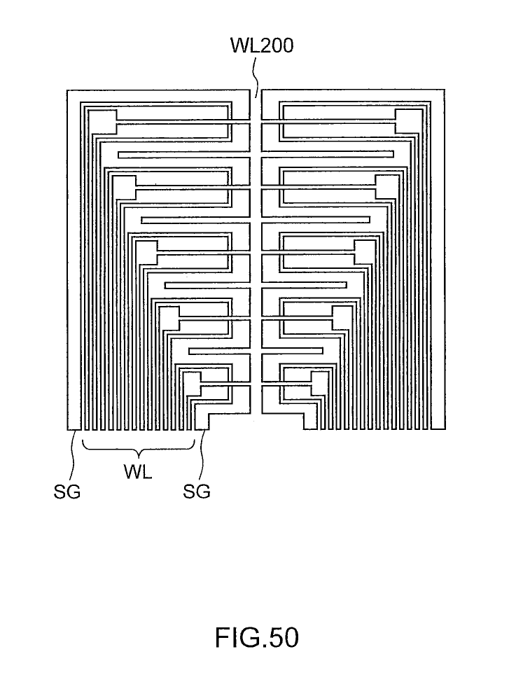

As shown in FIG. 49, a resist pattern RP200 provided with an opening OP100 to only separate the fringes in the lead-out area AR200 is formed and then etched. Thus, as shown in FIG. 50, a mask pattern shaped in such a manner that each word line is connected to the fringe is formed.

Finally, the resist patterns RP110 and RP200 on the mask patterns shown in FIG. 40A to FIG. 40C and in FIG. 50 are removed and then etched, and the mask pattern MP100 shown in FIG. 29 to FIG. 31 is thereby provided.

According to the manufacturing method of the mask pattern in the present embodiment, the bottom of the second sidewall film SW200 is previously transformed into SiON to prevent the production of a step between the first sidewall film SW100 and the silicon nitride (Si₃N₄) film SW300 when the second sidewall film SW200 is selectively etched and removed. Therefore, it is possible to provide a mask pattern having almost no variation in the height of the tops in the memory cell array area AR300. It is also possible to efficiently manufacture mask patterns not only in the memory cell array area AR300 but also in the lead-out area AR200 and the peripheral circuit area AR20.

According to the manufacturing method of the semiconductor device in the embodiments described above, the foundation fabrication target films are fabricated by using the mask patterns according to the aforementioned embodiments. it is therefore possible to form a satisfactory pattern without causing dimensional variation.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a semiconductor device, the method comprising:
manufacturing a mask pattern; and
forming an interconnection using the mask pattern,
the manufacturing the mask pattern comprising:
forming, on a fabrication target film, a first pattern of a first material comprising a line width which is a first width;
depositing a second material over the first pattern, and forming a first sidewall film on sidewalls of the first pattern by a first etchback, the thickness of the first sidewall film being the first width;
depositing a third material over the first sidewall film, forming a second sidewall film on sidewalls of the first sidewall film by a second etchback, and adjusting the first pattern and the second sidewall film so as to have the same height, the thickness of the second sidewall film being the first width; and
selectively removing the first sidewall film, thereby forming, on the fabrication target film, a mask pattern comprising a line-and-space, the line-and-space comprising a line width and a space width which are the first width.

2. The method of claim 1,
wherein the height of the first pattern becomes smaller than the height of the first sidewall film as a result of the first etchback.

3. The method of claim 1,
wherein the height of the first pattern becomes greater than the height of the first sidewall film as a result of the first etchback, and
the height of the first pattern becomes smaller together with the height of the second sidewall film as a result of the second etchback.

4. The method of claim 1,
wherein the first material and the material of the second sidewall film are different materials,
the mask pattern comprises a peripheral circuit pattern which is connected on one end to lines of the line-and-space and which is connected on the other end to fringes, and
the line-and-space and the peripheral circuit pattern are simultaneously formed.

5. The method of claim 4, wherein
the fringe is formed by forming a second pattern in the shape of a flag or joined flags, and forming, on the second pattern, a mask comprising an opening corresponding to joint portions, and then selectively removing the joint portions by an etchback,
space between the removed joint portions is changeable in accordance with the shape of the opening, and
the formed fringes are line-symmetrically arranged in such a manner that three fringes constitute one unit.

6. The method of claim 1,
wherein the first width is ⅓ of the line width of a resist pattern, and
the space width of the first pattern is 5/3 of the space width of the resist pattern.

7. A manufacturing method of a semiconductor device, the method comprising:
manufacturing a mask pattern; and
forming an interconnection using the mask pattern, the manufacturing the mask pattern comprising:
forming, on a fabrication target film, a first pattern of a first material comprising a line width which is a first width;
forming a first sidewall film of a second material on sidewalls of the first pattern, the thickness of the first sidewall film being the first width;
forming a second sidewall film of a third material on sidewalls of the first sidewall film, the thickness of the second sidewall film being the first width;
implanting an impurity into the top and bottom of the second sidewall film to partly increase etching resistance;
forming a film of a fourth material on the entire surface; and
removing the film of the fourth material until the top surface of the first pattern is exposed, and then removing the first pattern.

8. The method of claim 7,
wherein the mask pattern is used to manufacture a semiconductor memory device, and
forming the film of the fourth material comprises simultaneously forming a select gate.

9. The method of claim 8,
wherein the mask pattern comprises a mask pattern to form a peripheral transistor, and
the size of the end of a memory cell, the width of the select gate, and the size of the peripheral transistor are adjustable by the thickness of the film of the fourth material.

10. The method of claim 7,
wherein the mask pattern is used to manufacture a semiconductor memory device, and
the number N of word lines is provided by
N=2+(n−1)×3 (Equation 1)
in which n is the number of the first patterns.

11. The method of claim 7,
wherein the first material and the third material are the same material, and the second material and the fourth material are the same material.

12. The method of claim 7,
wherein the first width is ⅓ of the line width of a resist pattern, and
the space width of the first pattern is 5/3 of the space width of the resist pattern.
